(19) United States
(12) Patent Application Publication
(10) Pub. No.: US 2025/0095574 A1
(43) Pub. Date: Mar. 20, 2025

(54) DISPLAY DEVICE

(71) Applicant: Samsung Display Co., LTD., Yongin-si (KR)

(72) Inventors: YEONKYUNG KIM, Yongin-si (KR); DONGWOO KIM, Yongin-si (KR); KWIHYUN KIM, Yongin-si (KR)

(21) Appl. No.: 18/822,222

(22) Filed: Sep. 1, 2024

(30) Foreign Application Priority Data
Sep. 19, 2023 (KR) 10-2023-0124808

(51) Int. Cl. G09G 3/3233

(52) U.S. Cl. CPC G09G 3/3233; G09G 2300/0819; G09G 2300/0852; G09G 2300/0861; G09G 2310/08; G09G 2320/0242; G09G 2330/028

(57) ABSTRACT

A display device includes a plurality of pixels. Each of the plurality of pixels includes a light emitting element, a PWM circuit that controls an emission time of the light emitting element based on a PWM data voltage, a sweep voltage, and a reference voltage, a CCG circuit that provides a constant driving current to the light emitting element based on a constant current data voltage and a power supply voltage, and a connection switch that connects the PWM circuit to the CCG circuit. The light emitting elements substantially simultaneously start emitting light at a start time point of an emission period. In each pixel, the PWM circuit transfers the reference voltage to the CCG circuit through the connection switch at a time point corresponding to a voltage level of the PWM data voltage, and the CCG circuit causes the light emitting element to stop emitting light.

This application claims priority to Korean Patent Application No. 10-2023-0124808, filed on Sep. 19, 2023, and all the benefits accruing therefrom under 35 U.S.C. § 119, the content of which in its entirety is herein incorporated by reference.

### BACKGROUND

### 1. Field

Embodiments supported by aspects of the present disclosure relate to a display device, and more particularly to a display device that drives a light emitting element according to a pulse width modulation (PWM) method.

### 2. Description of the Related Art

A display device may display an image by driving a light emitting element, such as, for example, a micro light emitting diode (uLED) or an organic light emitting diode (OLED), according to a pulse amplitude modulation (PAM) method or a pulse width modulation (PWM) method. In the PAM method, a gray level may be represented by adjusting an amount (or an amplitude) of a driving current provided to the light emitting element. In the PWM method, the gray level may be represented by adjusting a time period (or a pulse width) during which the driving current is provided to the light emitting element.

A wavelength of light emitted by the uLED may be shifted according to the amount of the driving current. Thus, for example, in a case where the light emitting element such as, for example, the uLED is driven in the PAM method, a color shift phenomenon may occur, and the image may be distorted.

### SUMMARY

Some embodiments provide a display device that drives a light emitting element in a pulse width modulation (PWM) method.

According to embodiments, there is provided a display device including a plurality of pixels. Each of the plurality of pixels includes a light emitting element, a pulse width modulation (PWM) circuit configured to control an emission time of the light emitting element based on a PWM data voltage, a sweep voltage, and a reference voltage, a constant current generation (CCG) circuit configured to provide a constant driving current to the light emitting element based on a constant current data voltage and a power supply voltage, and a connection switch configured to connect the PWM circuit to the CCG circuit. The light emitting elements of the plurality of pixels substantially simultaneously start emitting light at a start time point of an emission period. In each of the plurality of pixels, the PWM circuit transfers the reference voltage to the CCG circuit through the connection switch at a time point corresponding to a voltage level of the PWM data voltage, and the CCG circuit causes the light emitting element to stop emitting light in response to the reference voltage. The reference voltage is applied to the PWM circuit, the power supply voltage is applied to the CCG circuit, and the reference voltage is higher than or equal to the power supply voltage.

In embodiments, a voltage level of the PWM data voltage for each of the plurality of pixels may be determined according to image data for each of the plurality of pixels, and the constant current data voltage may be provided to the plurality of pixels and be the same among the plurality of pixels.

In embodiments, the sweep voltage may be provided to the plurality of pixels and be the same among the plurality of pixels, and the sweep voltage may gradually decrease in the emission period.

In embodiments, the PWM circuit may include a first transistor including a gate, a first terminal, and a second terminal, a second transistor including a gate configured to receive a first writing signal, a first terminal connected to a first data line, and a second terminal connected to the first terminal of the first transistor, a third transistor including a gate configured to receive a first emission signal, a first terminal connected to a line associated with transferring the reference voltage, and a second terminal connected to the first terminal of the first transistor, a fourth transistor including a gate configured to receive a third writing signal, a first terminal connected to the second terminal of the first transistor, and a second terminal connected to the gate of the first transistor, and a first capacitor including a first electrode connected to a line associated with transferring the sweep voltage, and a second electrode connected to the gate of the first transistor.

In embodiments, the CCG circuit may include a sixth transistor including a gate configured to receive a second initialization signal, a first terminal connected to a line associated with transferring an anode initialization voltage, and a second terminal connected to an anode of the light emitting element, a seventh transistor including a gate, a first terminal, and a second terminal, an eighth transistor including a gate configured to receive a second writing signal, a first terminal connected to a second data line, and a second terminal connected to the first terminal of the seventh transistor, a ninth transistor including a gate configured to receive the first emission signal, a first terminal connected to a line associated with transferring the power supply voltage, and a second terminal connected to the first terminal of the seventh transistor, a tenth transistor including a gate configured to receive a fourth writing signal, a first terminal connected to the second terminal of the seventh transistor, and a second terminal connected to the gate of the seventh transistor, a second capacitor including a first electrode connected to the line associated with transferring the power supply voltage, and a second electrode connected to the gate of the seventh transistor, and an eleventh transistor including a gate configured to receive the first emission signal, a first terminal connected to the second terminal of the seventh transistor, and a second terminal connected to the anode of the light emitting element.

In embodiments, the PWM circuit may further include a fifth transistor including a gate configured to receive a first initialization signal, a first terminal connected to a line associated with transferring an initialization voltage, and a second terminal connected to the gate of the first transistor.

In embodiments, the connection switch may include a twelfth transistor including a gate configured to receive a second emission signal, a first terminal connected to the second terminal of the first transistor, and a second terminal connected to the gate of the seventh transistor.

In embodiments, a frame period for the display device may include an initialization period in which the gates of the first transistors of the plurality of pixels and the gates of the seventh transistors of the plurality of pixels are substantially simultaneously initialized, a PWM data writing period in which the PWM data voltages are sequentially written to the plurality of pixels on a row basis, a CCG data writing period in which the constant current data voltage is substantially simultaneously written to the plurality of pixels, and the emission period in which the light emitting elements of the plurality of pixels substantially simultaneously start emitting light.

In embodiments, in the initialization period, the first initialization signal, the third writing signal, and the second emission signal may have an on-level, and the initialization voltage may be applied to the gate of the first transistor through the fifth transistor, and the initialization voltage may be applied to the gate of the seventh transistor through the fifth transistor, the fourth transistor, and the twelfth transistor.

In embodiments, in the PWM data writing period, the first writing signal and the third writing signal may have an on-level, the fourth transistor may diode-connect the first transistor, and the PWM data voltage may be applied to the second electrode of the first capacitor through the second transistor and the diode-connected first transistor.

In embodiments, in the CCG data writing period, the second writing signal and the fourth writing signal may have an on-level, the tenth transistor may diode-connect the seventh transistor, and the constant current data voltage may be applied to the second electrode of the second capacitor through the eighth transistor and the diode-connected seventh transistor.

In embodiments, in the emission period, the first emission signal and the second emission signal may have an on-level, the sweep voltage may gradually decrease, the first transistor may turn on in response to the sweep voltage, the reference voltage may be applied to the seventh transistor through the third transistor, the first transistor and the twelfth transistor, and the seventh transistor may start providing the constant driving current to the light emitting element at the start time point of the emission period, and may stop providing the constant driving current in response to the reference voltage.

In embodiments, the second initialization signal may have an on-level in the initialization period, the PWM data writing period, and the CCG data writing period, and the sixth transistor may apply the anode initialization voltage to the anode of the light emitting element in the initialization period, the PWM data writing period, and the CCG data writing period.

In embodiments, the second initialization signal may have an on-level in the initialization period, and the sixth transistor may apply the anode initialization voltage to the anode of the light emitting element in the initialization period.

In embodiments, the first, second, third, sixth, seventh, eighth, ninth, eleventh and twelfth transistors may be P-type metal oxide semiconductor (PMOS) transistors, and the fourth, fifth and tenth transistors may be N-type metal oxide semiconductor (NMOS) transistors.

In embodiments, the first, second, third, sixth, seventh, eighth, ninth and eleventh transistors may be PMOS transistors, and the fourth, fifth, tenth and twelfth transistors may be NMOS transistors.

In embodiments, the first and second data lines may be different from each other.

In embodiments, the first and second data lines may be a same data line.

In embodiments, the CCG circuit may include a fifth transistor including a gate configured to receive a first initialization signal, a first terminal connected to a line associated with transferring an initialization voltage, and a second terminal connected to the gate of the seventh transistor.

According to embodiments, there is provided a display device including a plurality of pixels. Each of the plurality of pixels includes a light emitting element, a first transistor including a gate, a first terminal, and a second terminal, a second transistor including a gate configured to receive a first writing signal, a first terminal connected to a first data line, and a second terminal connected to the first terminal of the first transistor, a third transistor including a gate configured to receive a first emission signal, a first terminal connected to a line associated with transferring a reference voltage, and a second terminal connected to the first terminal of the first transistor, a fourth transistor including a gate configured to receive a third writing signal, a first terminal connected to the second terminal of the first transistor, and a second terminal connected to the gate of the first transistor, a first capacitor including a first electrode connected to a line associated with transferring a sweep voltage, and a second electrode connected to the gate of the first transistor, a fifth transistor including a gate configured to receive a first initialization signal, a first terminal connected to a line associated with transferring an initialization voltage, and a second terminal connected to the gate of the first transistor, a sixth transistor including a gate configured to receive a second initialization signal, a first terminal connected to a line associated with transferring an anode initialization voltage, and a second terminal connected to an anode of the light emitting element, a seventh transistor including a gate, a first terminal, and a second terminal, an eighth transistor including a gate configured to receive a second writing signal, a first terminal connected to a second data line, and a second terminal connected to the first terminal of the seventh transistor, a ninth transistor including a gate configured to receive the first emission signal, a first terminal connected to a line associated with transferring a power supply voltage, and a second terminal connected to the first terminal of the seventh transistor, a tenth transistor including a gate configured to receive a fourth writing signal, a first terminal connected to the second terminal of the seventh transistor, and a second terminal connected to the gate of the seventh transistor, a second capacitor including a first electrode connected to the line associated with transferring the power supply voltage, and a second electrode connected to the gate of the seventh transistor, an eleventh transistor including a gate configured to receive the first emission signal, a first terminal connected to the second terminal of the seventh transistor, and a second terminal connected to the anode of the light emitting element, and a twelfth transistor including a gate configured to receive a second emission signal, a first terminal connected to the second terminal of the first transistor, and a second terminal connected to the gate of the seventh transistor.

As described herein, in a display device according to embodiments, each pixel may include a light emitting element, a pulse width modulation (PWM) circuit, a constant current generation (CCG) circuit and a connection switch. Light emitting elements of a plurality of pixels may substantially simultaneously start emitting light at a start time point of an emission period. In each of the plurality of pixels, the PWM circuit may transfer a reference voltage to the CCG circuit through the connection switch at a time point corresponding to a voltage level of a PWM data voltage, and the CCG circuit may cause the light emitting element to stop emitting light in response to the reference voltage. The reference voltage applied to the PWM circuit may be higher than or equal to a power supply voltage applied to the CCG circuit. Accordingly, for example, the display device according to embodiments may drive the light emitting element in a PWM method, and the number of transistors and the number of capacitors of the pixel of the display device according to embodiments may be reduced compared with those of a conventional pixel.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to embodiments.

FIG. 2 is a block diagram illustrating an example of a pixel included in a display device according to embodiments.

FIG. 3 is a circuit diagram illustrating a pixel of a display device according to embodiments.

FIG. 4 is a timing diagram for describing an operation of a pixel according to embodiments.

FIG. 5 is a circuit diagram for describing an example of an operation of a pixel in an initialization period.

FIG. 6 is a circuit diagram for describing an example of an operation of a pixel in a PWM data writing period.

FIG. 7 is a circuit diagram for describing an example of an operation of a pixel in a CCG data writing period.

FIG. 8 is a circuit diagram for describing an example of an operation of a pixel in an emission period.

FIG. 9 is a timing diagram for describing an example of emission times according to PWM data voltages.

FIG. 10 is a timing diagram for describing an operation of a pixel according to embodiments.

FIG. 11 is a circuit diagram illustrating a pixel of a display device according to embodiments.

FIG. 12 is a timing diagram for describing an operation of a pixel according to embodiments.

FIG. 13 is a circuit diagram illustrating a pixel of a display device according to embodiments.

FIG. 14 is a timing diagram for describing an operation of a pixel according to embodiments.

FIG. 15 is a circuit diagram illustrating a pixel of a display device according to embodiments.

FIG. 16 is a block diagram illustrating an electronic device including a display device according to embodiments.

### DETAILED DESCRIPTION

Hereinafter, Embodiments supported by aspects of the present disclosure will be explained in detail with reference to the accompanying drawings.

Embodiments supported by the present disclosure will now be described more fully hereinafter with reference to the accompanying drawings, in which one or more example embodiments are shown. Aspects supported by the present disclosure may, however, be embodied in different forms and should not be construed as limited to the embodiments set forth herein. Rather, these example embodiments are provided such that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

The term “substantially,” as used herein, means approximately or actually equal (e.g., within a threshold percent of equal). The term “substantially simultaneously,” as used herein, means approximately or actually at the same time (e.g., within a threshold percent of equal). The term “substantially the same,” as used herein, means approximately or actually the same (e.g., within a threshold difference amount).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

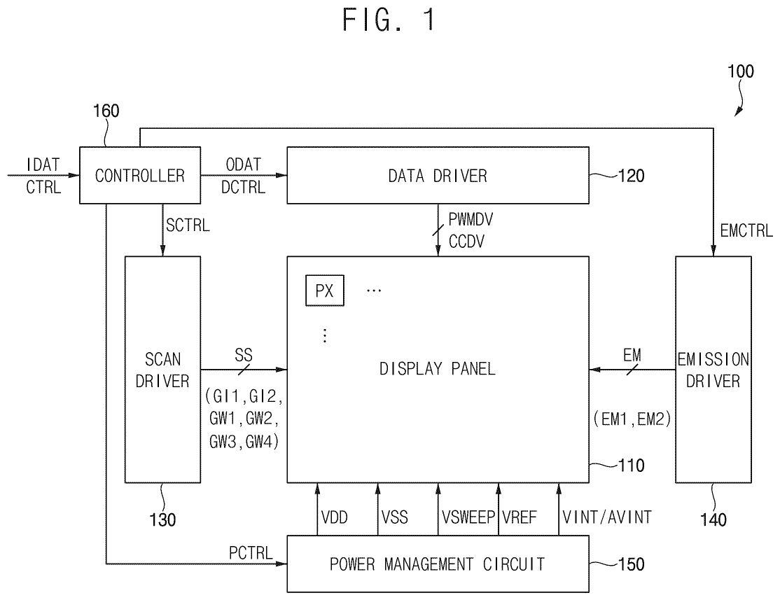

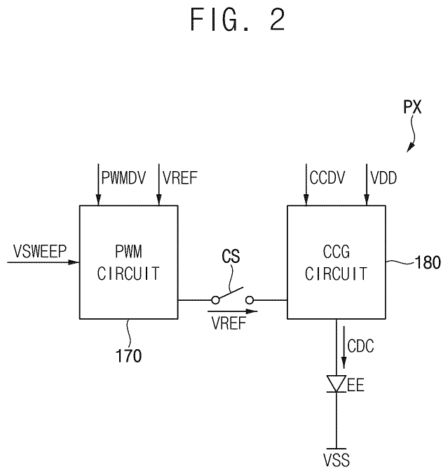

FIG. 1 is a block diagram illustrating a display device according to embodiments, and FIG. 2 is a block diagram illustrating an example of a pixel included in a display device according to embodiments.

Referring to FIG. 1, a display device 100 according to embodiments may include a display panel 110 including a plurality of pixels PX, a data driver 120 providing pulse width modulation (PWM) data voltages PWMDV and a constant current data voltage CCDV to the plurality of pixels PX, a scan driver 130 providing scan signals SS to the plurality of pixels PX, an emission driver 140 providing emission signals EM to the plurality of pixels PX, a power management circuit 150 providing voltages VDD, VSS, VSWEEP, VREF, and VINT to the plurality of pixels PX, and a controller 160 controlling the data driver 120, the scan driver 130, the emission driver 140, and the power management circuit 150.

The display panel 110 may include the plurality of pixels PX. As illustrated in FIG. 2, each pixel PX may include a light emitting element EE connected to a line associated with transferring a second power supply voltage VSS (e.g., a low power supply voltage). Each pixel PX may include a PWM circuit 170 that controls an emission time of the light emitting element EE based on the PWM data voltage PWMDV, a sweep voltage VSWEEP, and a reference voltage VREF. Each pixel PX may include a constant current generation (CCG) circuit 180 that provides a constant (or fixed) driving current CDC to the light emitting element EE based on the constant current data voltage CCDV and a first power supply voltage VDD (e.g., a high power supply voltage). Each pixel PX may include a connection switch CS that connects the PWM circuit 170 to the CCG circuit 180. In some embodiments, the light emitting element EE may be a micro-light emitting diode (uLED), but is not limited thereto. In other embodiments, the light emitting element EE may be an organic light emitting diode OLED. In some other embodiments, the light emitting element EE may be a nano light emitting diode (NED), a quantum dot (QD) light emitting diode, an inorganic light emitting diode, or any other suitable light emitting element.

The data driver 120 may provide the PWM data voltages PWMDV to the plurality of pixels PX based on a data control signal DCTRL and may output image data ODAT received from the controller 160. In addition, the data driver 120 may further provide the constant current data voltage CCDV to the plurality of pixels PX. In some embodiments, the data driver 120 may determine a voltage level of the PWM data voltage PWMDV for each pixel PX according to a gray level represented by the output image data ODAT for the pixel PX. For example, as the gray level represented by the output image data ODAT for each pixel PX increases, the data driver 120 may increase the voltage level of the PWM data voltage PWMDV for the pixel PX.

In some embodiments, the data driver 120 may provide the same constant current data voltage CCDV to the plurality of pixels PX. Thus, for example, the respective pixels PX may each generate a constant (or fixed) driving current CDC, in which the constant driving currents CDC generated by the pixels PX are substantially the same current level. In some embodiments, the data control signal DCTRL may include, but is not limited to, an output data enable signal, a horizontal start signal, and a load signal. In some embodiments, the data driver 120 and the controller 160 may be implemented as a single integrated circuit, and the single integrated circuit may be referred to as a timing controller embedded data driver (TED). In other embodiments, the data driver 120 and the controller 160 may be implemented as separate integrated circuits.

The scan driver 130 may provide the scan signals SS to the plurality of pixels PX based on a scan control signal SCTRL received from the controller 160. In some embodiments, the scan signal SS provided to each pixel PX may include a first initialization signal GI1, a second initialization signal GI2, a first writing signal GW1, a second writing signal GW2, a third writing signal GW3, and a fourth writing signal GW4, but is not limited thereto. In some embodiments, the scan control signal SCTRL may include, but is not limited to, a scan start signal and a scan clock signal. In some embodiments, the scan driver 130 may be integrated or formed in the display panel 110. In other embodiments, the scan driver 130 may be implemented as one or more integrated circuits.

The emission driver 140 may provide the emission signals EM to the plurality of pixels PX based on an emission control signal EMCTRL received from the controller 160. In some embodiments, the emission signal EM provided to each pixel PX may include a first emission signal EM1 and a second emission signal EM2, but is not limited thereto. In some embodiments, the emission control signal EMCTRL may include, but is not limited to, an emission start signal and an emission clock signal. In some embodiments, the emission driver 140 may be integrated or formed in the display panel 110. In other embodiments, the emission driver 140 may be implemented as one or more integrated circuits.

The power management circuit 150 may provide the first power supply voltage VDD, the second power supply voltage VSS, the sweep voltage VSWEEP, the reference voltage VREF, an initialization voltage VINT, and/or an anode initialization voltage AVINT to the plurality of pixels PX based on a power control signal PCTRL received from the controller 160. The first power supply voltage VDD may be a high power supply voltage, and the second power supply voltage VSS may be a low power supply voltage. The power management circuit 150 may provide the same sweep voltage VSWEEP to the plurality of pixels PX. In some embodiments, the power management circuit 150 may gradually decrease the sweep voltage VSWEEP in an emission period of each frame period.

The reference voltage VREF may be applied to the PWM circuit 170 of each pixel PX. The initialization voltage VINT may be used to initialize a gate of a driving transistor of the PWM circuit 170 and a gate of a driving transistor of the CCG circuit 180, and the anode initialization voltage AVINT may be used to initialize an anode of the light emitting element EE. In some embodiments, the power management circuit 150 may be implemented as an integrated circuit, and the integrated circuit may be referred to as a power management integrated circuit (PMIC). In other embodiments, the power management circuit 150 may be included in the controller 160 or may be included in the data driver 120.

The controller 160 (e.g., a timing controller) may receive input image data IDAT and a control signal CTRL from an external host processor (e.g., a graphics processing unit (GPU), an application processor (AP), or a graphics card). In some embodiments, the control signal CTRL may include, but is not limited to, a vertical synchronization signal, a horizontal synchronization signal, an input data enable signal, and a master clock signal. The controller 160 may generate the output image data ODAT, the data control signal DCTRL, the scan control signal SCTRL, the emission control signal EMCTRL, and the power control signal PCTRL based on the input image data IDAT and the control signal CTRL. The controller 160 may control the data driver 120 by providing the output image data ODAT and the data control signal DCTRL to the data driver 120, may control the scan driver 130 by providing the scan control signal SCTRL to the scan driver 130, may control the emission driver 140 by providing the emission control signal EMCTRL to the emission driver 140, and may control the power management circuit 150 by providing the power control signal PCTRL to the power management circuit 150.

In the display device 100 according to embodiments, the light emitting elements EE of the plurality of pixels PX may substantially simultaneously start emitting light at a start time point of the emission period of each frame period. In some aspects, emission end time points of the light emitting elements EE of the plurality of pixels PX may be determined according to the PWM data voltages PWMDV. That is, in each pixel PX, the PWM circuit 170 may transfer the reference voltage VREF to the CCG circuit 180 through the connection switch CS at a time point corresponding to the voltage level of the PWM data voltage PWMDV (expressed another way, in response to the voltage level of the PWM data voltage PWMDV, at a time point corresponding to the voltage level), and the CCG circuit 180 may cause the light emitting element EE to stop emitting light by stopping providing the constant driving current CDC to the light emitting element EE in response to the reference voltage VREF. The reference voltage VREF applied to the PWM circuit 170 may be higher than or equal to the first power supply voltage VDD applied to the CCG circuit 180. Accordingly, for example, the CCG circuit 180 may readily stop the light emission of the light emitting element EE in response to the reference voltage VREF provided from the PWM circuit 170. For example, the first power supply voltage VDD may be, but not be limited to, about 5V, and the reference voltage VREF may be any suitable voltage higher than about 5V. In an example, the reference voltage VREF may be, but not be limited to, about 6V.

As described herein, in the display device 100 according to embodiments, the light emitting elements EE of the plurality of pixels PX may substantially simultaneously start emitting light at time points corresponding to some voltage levels of the PWM data voltages PWMDV (e.g., voltage levels at which the light emitting elements EE emit light), and the light emitting elements EE may stop emitting light at time points corresponding to other voltage levels of the PWM data voltages PWMDV (e.g., voltage levels at which the light emitting elements EE refrain from emitting light). Accordingly, for example, the display device 100 may drive the light emitting elements EE in a PWM method. In some aspects, a conventional pixel driven in a PWM method may have nineteen transistors and three capacitors, but the pixel PX of the display device 100 according to embodiments may be implemented with fewer transistors and capacitors than the conventional pixel, which may reduce overhead costs, circuit complexity, and circuit area associated with implementing a pixel PX for a display device 100.

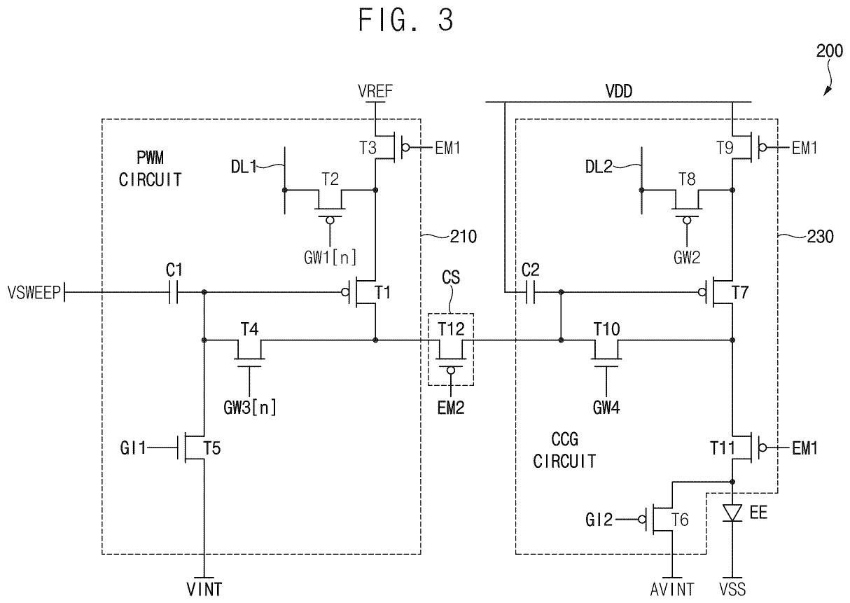

FIG. 3 is a circuit diagram illustrating a pixel of a display device according to embodiments.

Referring to FIG. 3, a pixel 200 according to embodiments may include a PWM circuit 210, a CCG circuit 230, a connection switch CS, and a light emitting element EE. In some embodiments, the PWM circuit 210 may include a first transistor T1, a second transistor T2, a third transistor T3, a fourth transistor T4, a fifth transistor T5, and a first capacitor C1. The CCG circuit 230 may include a sixth transistor T6, a seventh transistor T7, an eighth transistor T8, a ninth transistor T9, a tenth transistor T10, an eleventh transistor T11, and a second capacitor C2. The connection switch CS may include a twelfth transistor T12.

The first transistor T1 may turn on in response to a sweep voltage VSWEEP applied by coupling of the first capacitor C1. In some aspects, a time point at which the first transistor T1 turns on may be determined according to a voltage level of a PWM data voltage. In some embodiments, the first transistor T1 may include a gate connected to the first capacitor C1, a first terminal connected to the second and third transistors T2 and T3, and a second terminal connected to the fourth and twelfth transistors T4 and T12.

The second transistor T2 may transfer the PWM data voltage of a first data line DL1 to the first terminal of the first transistor T1 in response to a first writing signal GW1[n]. In some embodiments, the first writing signal GW1[n] may be sequentially applied to a plurality of pixels 200 of a display panel on a row-by-row basis. In some embodiments, the second transistor T2 may include a gate configured to receive the first writing signal GW1[n], a first terminal connected to the first data line DL1, and a second terminal connected to the first terminal of the first transistor T1.

The third transistor T3 may transfer a reference voltage VREF to the first terminal of the first transistor T1 in response to a first emission signal EM1. In some embodiments, the first emission signal EM1 may be substantially simultaneously applied to the plurality of pixels 200 in two or more rows. For example, the first emission signal EM1 may be substantially simultaneously applied to all pixels 200 of the display panel. In some embodiments, the third transistor T3 may include a gate configured to receive the first emission signal EM1, a first terminal connected to a line associated with transferring the reference voltage VREF (e.g., a line via which the power management circuit 150 may provide the reference voltage VREF), and a second terminal connected to the first terminal of the first transistor T1.

The fourth transistor T4 may diode-connect the first transistor T1 in response to a third writing signal GW3[n]. In some embodiments, the third writing signal GW3[n] may be sequentially applied to the plurality of pixels 200 of the display panel on a row-by-row basis. In some embodiments, the fourth transistor T4 may include a gate configured to receive the third writing signal GW3[n], a first terminal connected to the second terminal of the first transistor T1, and a second terminal connected to the gate of the first transistor T1.

The fifth transistor T5 may transfer an initialization voltage VINT to the gate of the first transistor T1 in response to a first initialization signal GI1. In addition, the initialization voltage VINT applied to the gate of the first transistor T1 may be further applied to a gate of the seventh transistor T7 through the fourth and twelfth transistors T4 and T12. In some embodiments, the first initialization signal GI1 may be substantially simultaneously applied to the plurality of pixels 200 arranged in two or more rows. For example, the first initialization signal GI1 may be substantially simultaneously applied to all pixels 200 of the display panel. In some embodiments, the fifth transistor T5 may include a gate configured to receive the first initialization signal GI1, a first terminal connected to a line associated with transferring the initialization voltage VINT (e.g., a line via which the power management circuit 150 may provide the initialization voltage VINT), and a second terminal connected to the gate of the first transistor T1.

The first capacitor C1 may be connected between a line associated with transferring the sweep voltage VSWEEP (e.g., a line via which the power management circuit 150 may provide the voltage VSWEEP) and the gate of the first transistor T1. In some embodiments, the first capacitor C1 may include a first electrode connected to the line associated with transferring the sweep voltage VSWEEP and a second electrode connected to the gate of the first transistor T1.

The sixth transistor T6 may transfer an anode initialization voltage AVINT to an anode of the light emitting element EE in response to a second initialization signal GI2. In some embodiments, the second initialization signal GI2 may be substantially simultaneously applied to the plurality of pixels 200 arranged in two or more rows. For example, the second initialization signal GI2 may be substantially simultaneously applied to all pixels 200 of the display panel. In some embodiments, the initialization voltage VINT for initializing the gates of the first and seventh transistors T1 and T7 and the anode initialization voltage AVINT for initializing the anode of the light emitting element EE may be the same voltage transferred through the same line. In other embodiments, the anode initialization voltage AVINT for initializing the anode of the light emitting element EE may be different from the initialization voltage VINT for initializing the gates of the first and seventh transistors T1 and T7. In some embodiments, the sixth transistor T6 may include a gate configured to receive the second initialization signal GI2, a first terminal connected to a line associated with transferring the anode initialization voltage AVINT (e.g., a line via which the power management circuit 150 may provide the anode initialization voltage AVINT), and a second terminal connected to the anode of the light emitting element EE.

The seventh transistor T7 may generate a constant (or fixed) driving current based on a constant current data voltage of a second data line DL2. In some embodiments, the seventh transistor T7 may include a gate connected to the second capacitor C2, a first terminal connected to the eighth and ninth transistors T8 and T9, and a second terminal connected to the tenth and eleventh transistors T10 and T11.

The eighth transistor T8 may transfer the constant current data voltage of the second data line DL2 to the first terminal of the seventh transistor T7 in response to a second writing signal GW2. In some embodiments, the second writing signal GW2 may be substantially simultaneously applied to the plurality of pixels 200 in two or more rows. For example, the second writing signal GW2 may be substantially simultaneously applied to all pixels 200 of the display panel. In some embodiments, as illustrated in FIG. 3, the first and second data lines DL1 and DL2 may be different data lines. In some embodiments, the eighth transistor T8 may include a gate configured to receive the second writing signal GW2, a first terminal connected to the second data line DL2, and a second terminal connected to the first terminal of the seventh transistor T7.

The ninth transistor T9 may transfer a first power supply voltage VDD to the first terminal of the seventh transistor T7 in response to the first emission signal EM1. In some embodiments, the ninth transistor T9 may include a gate configured to receive the first emission signal EM1, a first terminal connected to a line associated with transferring the first power supply voltage VDD (e.g., a line via which the power management circuit 150 may provide the power supply voltage VDD), and a second terminal connected to the first terminal of the seventh transistor T7.

The tenth transistor T10 may diode-connect the seventh transistor T7 in response to a fourth writing signal GW4. In some embodiments, the fourth writing signal GW4 may be substantially simultaneously applied the plurality of pixels 200 in two or more rows. For example, the fourth writing signal GW4 may be substantially simultaneously applied to all pixels 200 of the display panel. In some embodiments, the tenth transistor T10 may include a gate configured to receive the fourth writing signal GW4, a first terminal connected to the second terminal of the seventh transistor T7, and a second terminal connected to the gate of the seventh transistor T7.

The eleventh transistor T11 may connect the second terminal of the seventh transistor T7 to the anode of the light emitting element EE in response to the first emission signal EM1. In some embodiments, the eleventh transistor T11 may include a gate configured to receive the first emission signal EM1, a first terminal connected to the second terminal of the seventh transistor T7, and a second terminal connected to the anode of the light emitting element EE.

The second capacitor C2 may be connected between the line associated with transferring the first power supply voltage VDD and the gate of the seventh transistor T7. In some embodiments, the second capacitor C2 may include a first electrode connected to the line associated with transferring the first power supply voltage VDD and a second electrode connected to the gate of the seventh transistor T7.

The twelfth transistor T12 may connect the PWM circuit 210 to the CCG circuit 230 in response to a second emission signal EM2. For example, the twelfth transistor T12 may connect the second terminal of the first transistor T1 to the gate of the seventh transistor T7. In some embodiments, the second emission signal EM2 may be substantially simultaneously applied to a plurality of pixels 200 in two or more rows. For example, the second emission signal EM2 may be substantially simultaneously applied to all pixels 200 of the display panel. In some embodiments, the twelfth transistor T12 may include a gate configured to receive the second emission signal EM2, a first terminal connected to the second terminal of the first transistor T1, and a second terminal connected to the gate of the seventh transistor T7.

The light emitting element EE may emit light based on the constant driving current. For example, the light emitting element EE may be a micro light emitting diode, an organic light emitting diode, a nano light emitting diode, a quantum dot light emitting diode, an inorganic light emitting diode, or any other suitable light emitting element. In some embodiments, the light emitting element EE may include an anode connected to the sixth and eleventh transistors T6 and T11, and the light emitting element EE may include a cathode connected to a line associated with transferring a second power supply voltage VSS.

In some embodiments, the pixel 200 may include at least one P-type metal oxide semiconductor (PMOS) transistor and at least one N-type metal oxide semiconductor (NMOS) transistor, but is not limited thereto. For example, as illustrated in FIG. 3, the first, second, third, sixth, seventh, eighth, ninth, eleventh and twelfth transistors T1, T2, T3, T6, T7, T8, T9, T11, and T12 may be PMOS transistors, and the fourth, fifth and tenth transistors T4, T5, and T10 may be NMOS transistors.

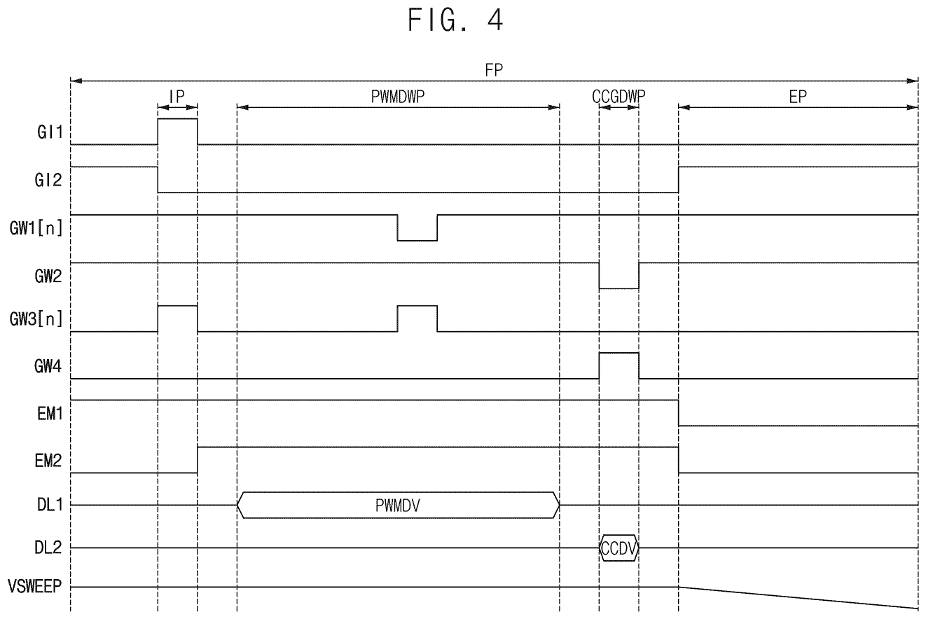

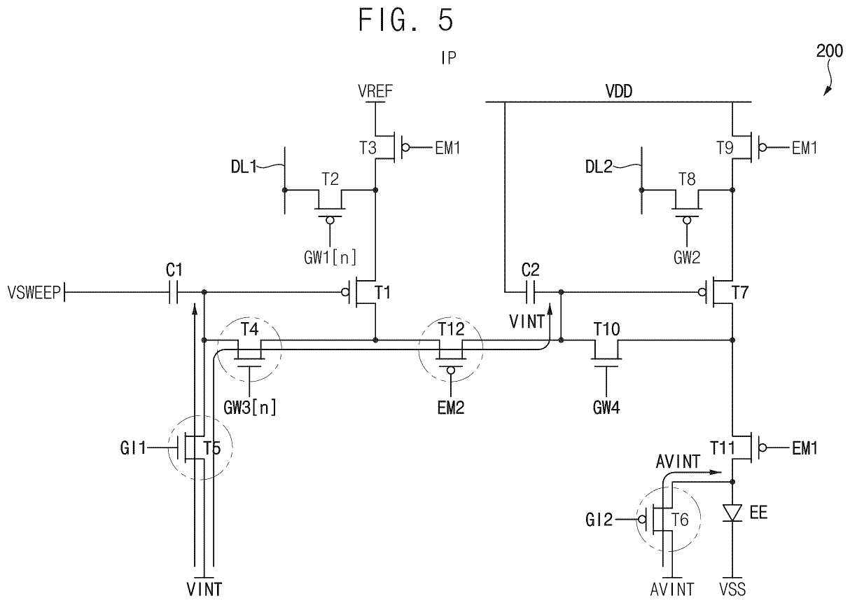

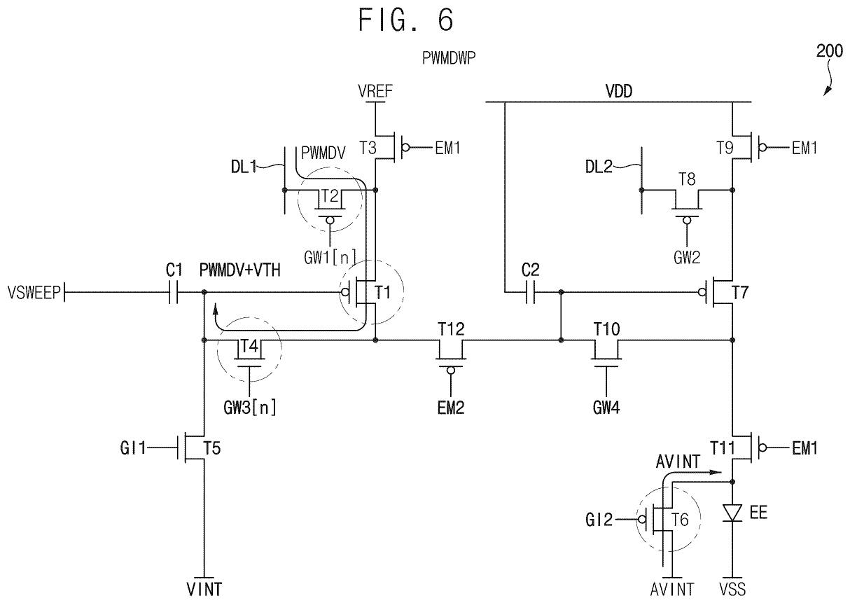

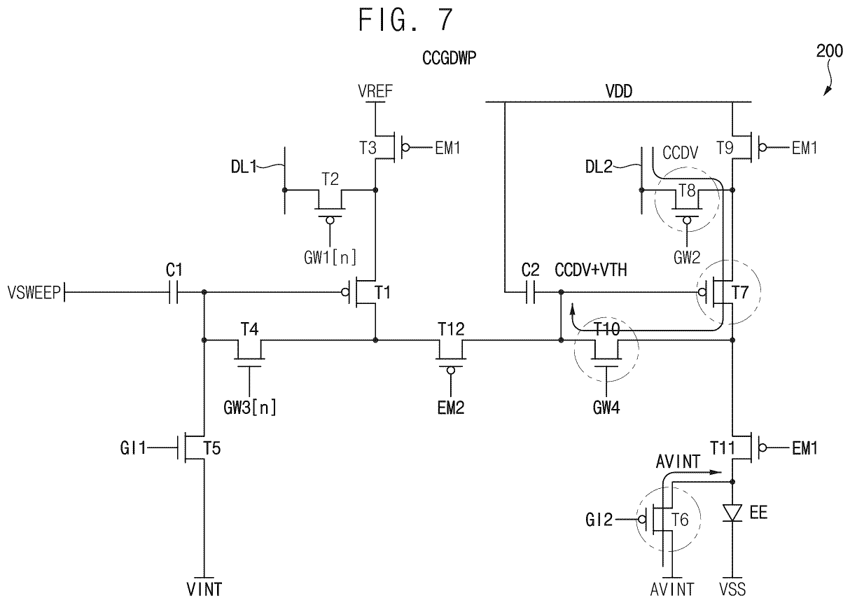

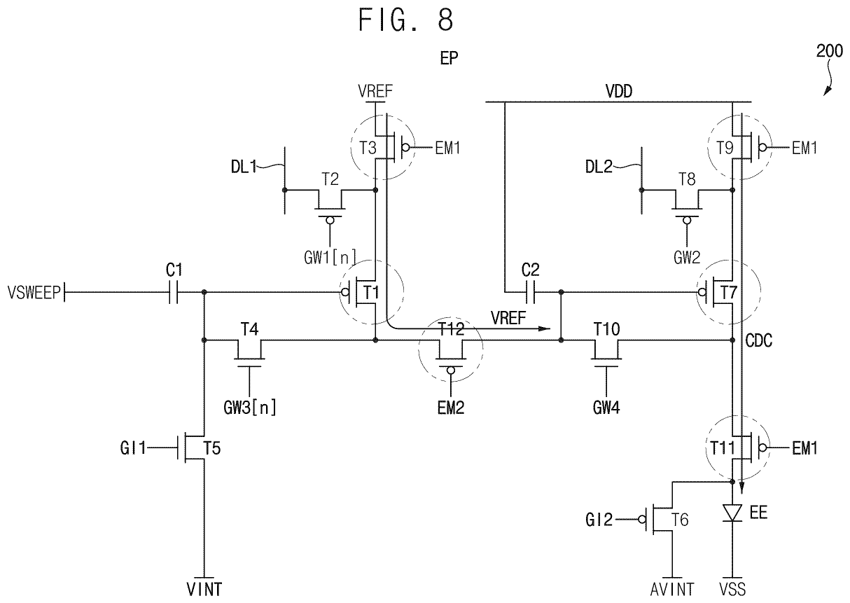

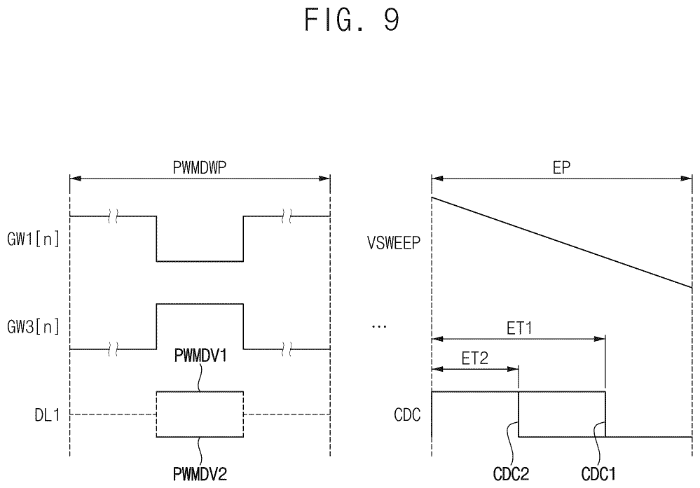

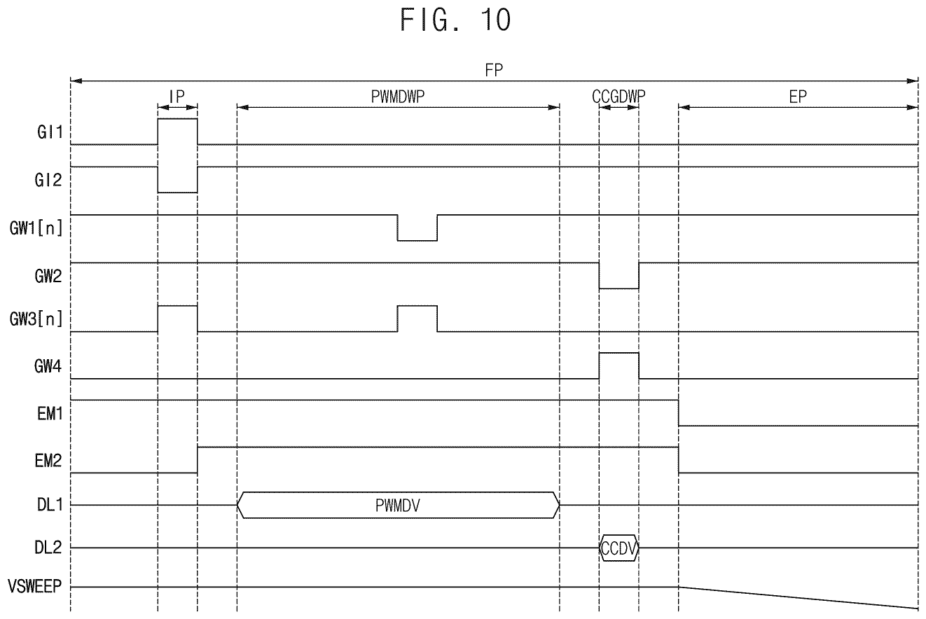

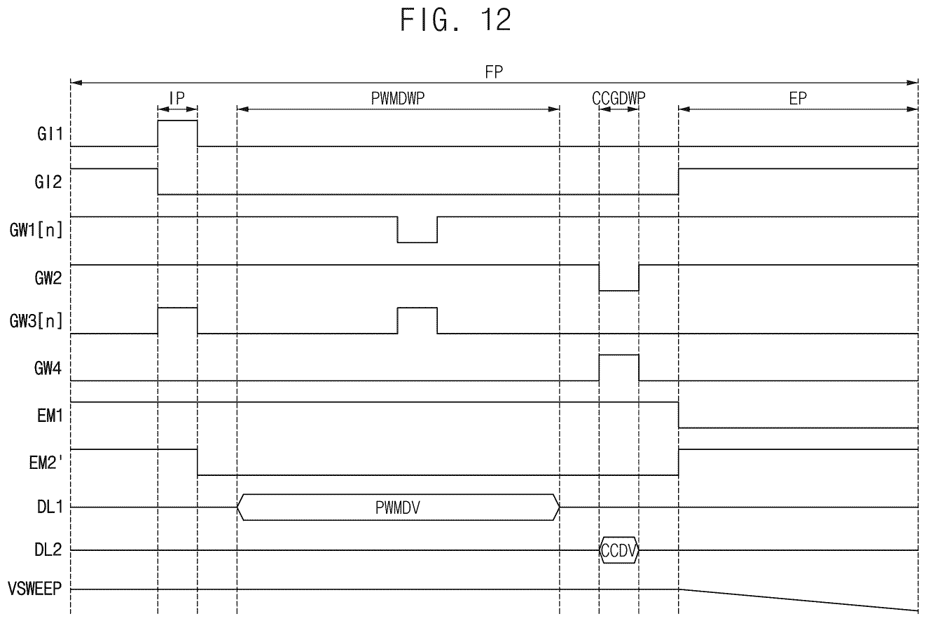

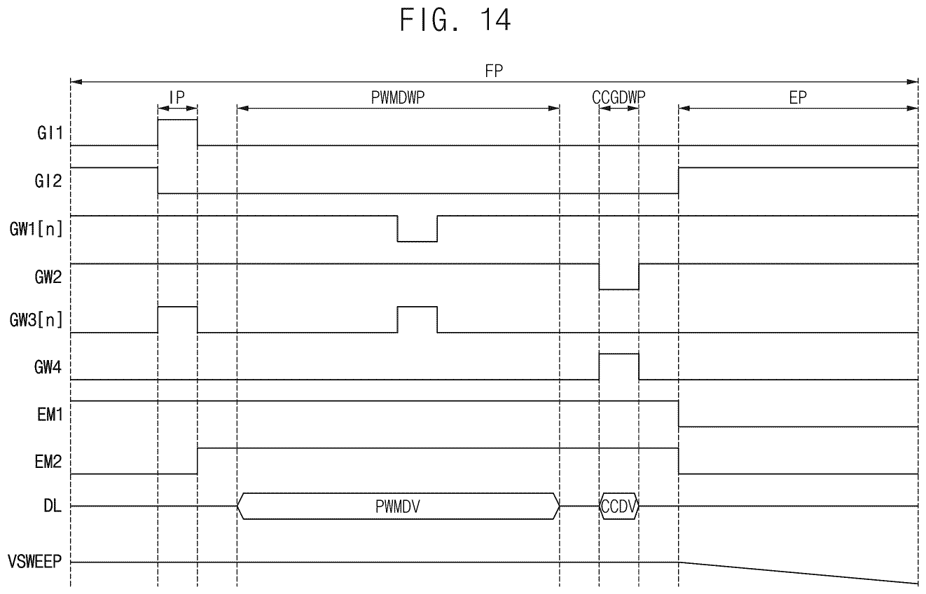

FIG. 4 is a timing diagram for describing an operation of a pixel according to embodiments, FIG. 5 is a circuit diagram for describing an example of an operation of a pixel in an initialization period, FIG. 6 is a circuit diagram for describing an example of an operation of a pixel in a PWM data writing period, FIG. 7 is a circuit diagram for describing an example of an operation of a pixel in a CCG data writing period, FIG. 8 is a circuit diagram for describing an example of an operation of a pixel in an emission period, and FIG. 9 is a timing diagram for describing an example of emission times according to PWM data voltages. In the timing diagrams illustrated herein (e.g., FIG. 4, FIG. 10, FIG. 12, and FIG. 14), it is to be understood that the Y-axis of the timing diagrams may represent a value (e.g., voltage) and the X-axis may represent another value (e.g., time).

Referring to FIGS. 3 and 4, a frame period FP for a display device including a pixel 200 may include an initialization period IP in which gates of first transistors T1 of a plurality of pixels 200 of a display panel and gates of seventh transistors T7 of the plurality of pixels 200 are substantially simultaneously initialized. The frame period FP may include a PWM data writing period PWMDWP in which PWM data voltages PWMDV are sequentially written to the plurality of pixels 200 on a row by row basis. The frame period FP may include a CCG data writing period CCGDWP in which a constant current data voltage CCDV is substantially simultaneously written to the plurality of pixels 200. The frame period FP may include an emission period EP in which light emitting elements EE of the plurality of pixels 200 may substantially simultaneously start emitting light.

In the initialization period IP, a first initialization signal GI1, a second initialization signal GI2, a third writing signal GW3[n], and a second emission signal EM2 may have an on-level. For example, in the initialization period IP, all of the third writing signals GW3[n] applied to the plurality of pixels 200 may have the on-level. Descriptions of a signal “having an on-level” may refer to the signal being of a signal level (e.g., voltage level) at which a component (e.g., a transistor) which receives the signal turns on.

As illustrated in FIG. 5, a fifth transistor T5 may turn on in response to the first initialization signal GI1 and may transfer an initialization voltage VINT to a gate of the first transistor T1. Thus, for example, the gate of the first transistor T1 may be initialized based on the initialization voltage VINT. In some aspects, a fourth transistor T4 may turn on in response to the third writing signal GW3[n], a twelfth transistor T12 may turn on in response to the second emission signal EM2, and thus the initialization voltage VINT may be further applied to a gate of the seventh transistor T7 through the fifth transistor T5, the fourth transistor T4, and the twelfth transistor T12. Accordingly, for example, the gate of the seventh transistor T7 also may be initialized based on the initialization voltage VINT. In some aspects, a sixth transistor T6 may turn on in response to the second initialization signal GI2 and may transfer an anode initialization voltage AVINT to an anode of the light emitting element EE. Thus, for example, the anode of the light emitting element EE may be initialized based on the anode initialization voltage AVINT.

In the PWM data write period PWMDWP, first writing signal GW1[n] and third writing signal GW3[n] for the plurality of pixels 200 of the display panel may sequentially have the on-level on a row-by-row basis. While the first writing signal GW1[n] and third writing signal GW3[n] for the pixel 200 have the on-level, as illustrated in FIG. 6, the second transistor T2 may turn on in response to the first writing signal GW1[n], and the fourth transistor T4 may turn on in response to the third writing signal GW3[n]. The second transistor T2 may transfer the PWM data voltage PWMDV of a first data line DL1 to a first terminal of the first transistor T1, and the fourth transistor T4 may diode-connect the first transistor T1. Thus, for example, the PWM data voltage PWMDV may be applied to a second electrode of a first capacitor C1 through the diode-connected first transistor T1, and the gate of the first transistor T1 or the second electrode of the first capacitor C1 may have a voltage corresponding to a sum of the PWM data voltage PWMDV and a threshold voltage VTH of the first transistor T1. The described operation may be referred to as a threshold voltage compensation operation for the first transistor T1. In some aspects, in the PWM data writing period PWMDWP, the second initialization signal GI2 may have the on-level, the sixth transistor T6 may transfer the anode initialization voltage AVINT to the anode of the light emitting element EE in response to the second initialization signal GI2, and the anode of the light emitting element EE may be initialized based on the anode initialization voltage AVINT.

In the CCG data write period CCGDWP, a second writing signal GW2 and a fourth writing signal GW4 may have the on-level. As illustrated in FIG. 7, an eighth transistor T8 may turn on in response to the second writing signal GW2, and a tenth transistor T10 may turn on in response to the fourth writing signal GW4. The eighth transistor T8 may transfer the constant current data voltage CCDV of a second data line DL2 to a first terminal of the seventh transistor T7, and the tenth transistor T10 may diode-connect the seventh transistor T7. Thus, for example, the constant current data voltage CCDV may be applied to a second electrode of a second capacitor C2 through the diode-connected seventh transistor T7, and the gate of the seventh transistor T7 or the second electrode of the second capacitor C2 may have a voltage corresponding to a sum of the constant current data voltage CCDV and a threshold voltage VTH of the seventh transistor T7. The described operation may be referred to as a threshold voltage compensation operation for the seventh transistor T7. In some aspects, in the CCG data writing period CCGDWP, the second initialization signal GI2 may have the on-level, the sixth transistor T6 may transfer the anode initialization voltage AVINT to the anode of the light emitting element EE in response to the second initialization signal GI2, and the anode of the light emitting element EE may be initialized based on the anode initialization voltage AVINT.

In the emission period EP, a first emission signal EM1 and the second emission signal EM2 may have the on-level. As illustrated in FIG. 8, in each pixel 200, ninth and eleventh transistors T9 and T11 may turn on in response to the first emission signal EM1, and the seventh transistor T7 may generate a constant (or fixed) driving current CDC based on the voltage at the second electrode of the second capacitor C2. In an example, the voltage at the second electrode of the second capacitor C2 corresponds to the sum of the constant current data voltage CCDV and the threshold voltage VTH of the seventh transistor T7. Since the threshold voltage VTH of the seventh transistor T7 is reflected in the voltage at the second electrode of the second capacitor C2, even if the seventh transistors T7 of the plurality of pixels 200 have different threshold voltages VTH, the seventh transistors T7 of the plurality of pixels 200 may generate the constant driving current CDC having substantially the same current level. Thus, for example, the seventh transistors T7 of the plurality of pixels 200 may substantially simultaneously start providing the same constant driving current CDC to the light emitting elements EE of the plurality of pixels 200 at a start time point of the emission period EP, and the light emitting elements EE of the plurality of pixels 200 may substantially simultaneously start emitting light at the start time point of the emission period EP.

A third transistor T3 may turn on in response to the first emission signal EM1, and the twelfth transistor T12 may turn on in response to the second emission signal EM2. In some aspects, the same sweep voltage VSWEEP may be provided to the plurality of pixels 200, and the sweep voltage VSWEEP may gradually decrease in the emission period EP. In each pixel 200, the sweep voltage VSWEEP may be applied to the gate of the first transistor T1 through the first capacitor C1. Thus, for example, as the sweep voltage VSWEEP gradually decreases, a voltage of the gate of the first transistor T1 also may gradually decrease from the sum of the PWM data voltage PWMDV and the threshold voltage VTH of the first transistor T1. In an example in which the voltage of the gate of the first transistor T1 is gradually decreased by the decrease of the sweep voltage VSWEEP, the first transistor T1 may turn on. Since the threshold voltage VTH of the first transistor T1 is reflected in the voltage of the gate of the first transistor T1, even in a case in which the first transistors T1 of the plurality of pixels 200 of the display panel have different threshold voltages VTH, a time point at which the first transistor T1 of each pixel 200 is turned on may be independent of (e.g., may not be changed according to) the threshold voltage VTH of the first transistor T1, and the time point may depend on a voltage level of the PWM data voltage PWMDV applied to the pixel 200. In an example in which the first transistor T1 is turned on, a reference voltage VREF may be applied to the gate of the seventh transistor T7 through the third transistor T3, the first transistor T1, and the twelfth transistor T12, and the seventh transistor T7 may stop providing the constant driving current CDC in response to the reference voltage VREF, and thus the light emitting element EE may stop emitting light.

As described herein, an emission time of each pixel 200 may be determined according to the voltage level of the PWM data voltage PWMDV applied to the pixel 200. For example, as illustrated in FIG. 9, in a case where a first PWM data voltage PWMDV1 having a relatively high voltage level is applied to the pixel 200, the first transistor T1 may remain in a turned-off state until the sweep voltage VSWEEP reaches a relatively low voltage level. That is, for example, the first transistor T1 may have be in the turned-off state for a relatively long first emission time ET1. Thus, for example, in the case where the first PWM data voltage PWMDV1 having the relatively high voltage level is applied, during the relatively long first emission time ET1, the seventh transistor T7 may provide a first constant driving current CDC1 to the light emitting element EE, and the light emitting element EE may emit light based on the first constant driving current CDC1.

After the first emission time ET1, the first transistor T1 may turn on, and the seventh transistor T7 may turn off (enter a turned-off state) based on the reference voltage VREF. Alternatively, in a case where a second PWM data voltage PWMDV2 having a relatively low voltage level is applied to the pixel 200, the first transistor T1 may remain in the turned-off state until (e.g., only until) the sweep voltage VSWEEP reaches a relatively high voltage level. That is, the first transistor T1 may be in the turned-off state for a relatively short second emission time ET2. Thus, for example, in the case where the second PWM data voltage PWMDV2 having the relatively low voltage level is applied, during the relatively short second emission time ET2, the seventh transistor T7 may provide a second constant driving current CDC2 to the light emitting element EE, and the light emitting element EE may emit light based on the second constant driving current CDC2.

After the second emission time ET2, the first transistor T1 may turn on, and the seventh transistor T7 may turn off based on the reference voltage VREF. As described herein, the emission time ET1 and ET2 of each pixel 200 may be determined according to the voltage level of the PWM data voltage PWMDV1 and PWMDV2, and thus each pixel 200 may be driven in the PWM method. The emission time ET1 and emission time ET2 may be referred to as emission durations or emission periods.

FIG. 10 is a timing diagram for describing an operation of a pixel according to embodiments.

The timing diagram of FIG. 10 includes aspects of timing diagram of FIG. 4 described herein, and repeated descriptions of like elements are omitted for brevity. The timing diagram of FIG. 10 may be substantially the same as the timing diagram of FIG. 4, except that a second initialization signal GI2 has an on-level (e.g., a low voltage level, a logic level low, or the like) in an initialization period IP.

Referring to FIGS. 3 and 10, the second initialization signal GI2 may have the on-level in the initialization period IP, sixth transistor T6 may apply an anode initialization voltage AVINT to an anode of a light emitting element EE in the initialization period IP, and the anode of the light emitting element EE may be initialized based on the anode initialization voltage AVINT in the initialization period IP.

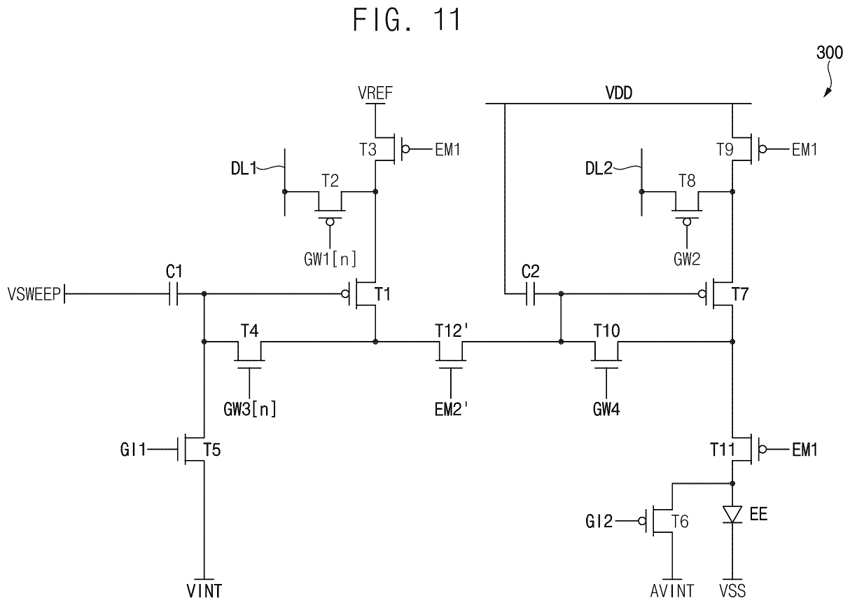

FIG. 11 is a circuit diagram illustrating a pixel of a display device according to embodiments, and FIG. 12 is a timing diagram for describing an operation of the pixel according to embodiments.

Referring to FIG. 11, a pixel 300 may include a first transistor T1, a second transistor T2, a third transistor T3, a fourth transistor T4, a fifth transistor T5, a sixth transistor T6, a seventh transistor T7, an eighth transistor T8, a ninth transistor T9, a tenth transistor T10, an eleventh transistor T11, a twelfth transistor T12′, a first capacitor C1, a second capacitor C2 and a light emitting element EE. The pixel 300 of FIG. 11 may have a configuration and an operation substantially the same as the configuration and operation of a pixel 200 of FIG. 3, except that the twelfth transistor T12′ is an NMOS transistor.

In some embodiments, the pixel 300 may include at least one P-type metal oxide semiconductor (PMOS) transistor and at least one N-type metal oxide semiconductor (NMOS) transistor, but is not limited thereto. For example, as illustrated in FIG. 11, the first, second, third, sixth, seventh, eighth, ninth and eleventh transistors T1, T2, T3, T6, T7, T8, T9, and T11 may be PMOS transistors, and the fourth, fifth, tenth and twelfth transistors T4, T5, T10, and

T12′ may be NMOS transistors.

As illustrated in FIG. 12, the twelfth transistor T12′ that is the NMOS transistor may receive a second emission signal EM2′ that is an active high signal having a high level as an on-level and a low level as an off-level. The timing diagram of FIG. 12 may be substantially the same as a timing diagram of FIG. 4, except that the second emission signal EM2′ is an active high signal.

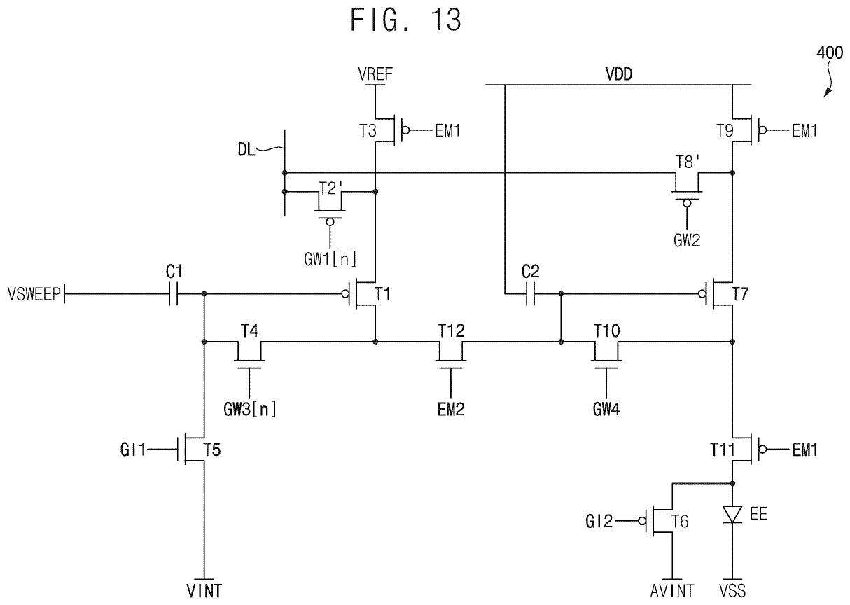

FIG. 13 is a circuit diagram illustrating a pixel of a display device according to embodiments, and FIG. 14 is a timing diagram for describing an operation of the pixel according to embodiments.

Referring to FIG. 13, a pixel 400 may include a first transistor T1, a second transistor T2′, a third transistor T3, a fourth transistor T4, a fifth transistor T5, a sixth transistor T6, a seventh transistor T7, an eighth transistor T8′, a ninth transistor T9, a tenth transistor T10, an eleventh transistor T11, a twelfth transistor T12, a first capacitor. C1, a second capacitor C2, and a light emitting element EE. The pixel 400 of FIG. 13 may have a configuration and an operation substantially the same as the configuration and operation of a pixel 200 of FIG. 3, except that the second and eighth transistors T2′ and T8′ are connected to the same data line DL.

In the pixel 400, the data line DL to which a PWM data voltage PWMDV is applied may be substantially the same as the data line DL to which a constant current data voltage CCDV is applied. Thus, for example, as illustrated in FIG. 14, in a PWM data writing period PWMDWP, the PWM data voltage PWMDV may be applied to the data line DL, and the second transistor T2′ may transfer the PWM data voltage PWMDV of the data line DL to a first terminal of the first transistor T1. In some aspects, in a CCG data writing period CCGDWP, the constant current data voltage CCDV may be applied to the data line DL, and the eighth transistor T8′ may transfer the constant current data voltage CCDV of the data line DL to a first terminal of the seventh transistor T7.

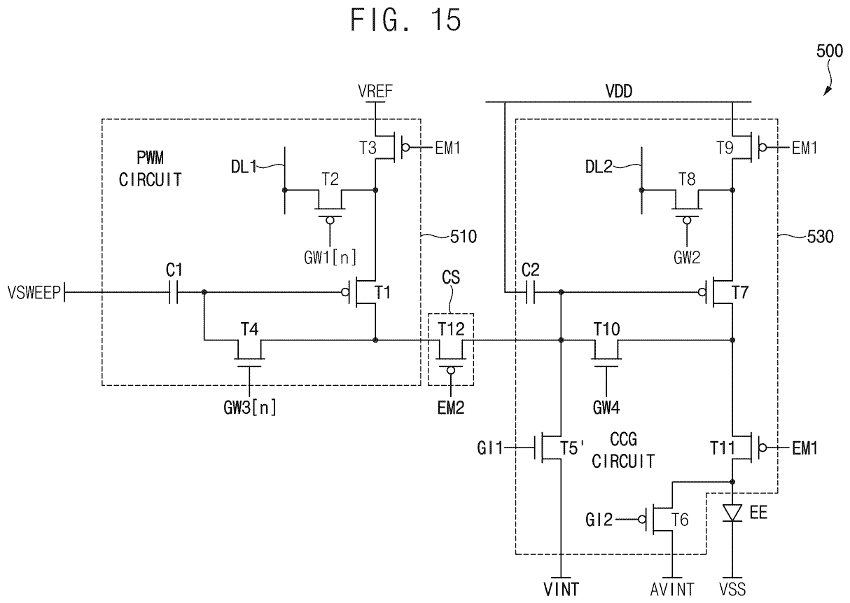

FIG. 15 is a circuit diagram illustrating a pixel of a display device according to embodiments.

Referring to FIG. 15, a pixel 500 may include a PWM circuit 510, a CCG circuit 530, a connection switch CS, and a light emitting element EE. The PWM circuit 510 may include a first transistor T1, a second transistor T2, a third transistor T3, a fourth transistor T4, and a first capacitor C1. The CCG circuit 230 may include a fifth transistor T5′, a sixth transistor T6, a seventh transistor T7, an eighth transistor T8, a ninth transistor T9, a tenth transistor T10, an eleventh transistor T11, and a second capacitor C2. The connection switch CS may include a twelfth transistor T12. The pixel 500 of FIG. 15 may have a configuration and an operation substantially the same as the configuration and operation of a pixel 200 of FIG. 3, except that the CCG circuit 530 may include the fifth transistor T5′.

The fifth transistor T5′ may transfer an initialization voltage VINT to a gate of the seventh transistor T7 in response to a first initialization signal GI1. In some aspects, the initialization voltage VINT applied to the gate of the seventh transistor T7 may be further applied to a gate of the first transistor T1 through the twelfth transistor T12 and the fourth transistor T4. In some embodiments, the fifth transistor T5′ may include a gate configured to receive the first initialization signal GI1, a first terminal connected to a line associated with transferring the initialization voltage VINT (e.g., a line via which the power management circuit 150 may provide the initialization voltage VINT), and a second terminal connected to the gate of the seventh transistor T7.

Those skilled in the art will appreciate that the present disclosure supports any suitable combination of the embodiments described herein with reference to FIGS. 1 to 15. For example, in the embodiment of the pixel 500 illustrated in FIG. 15, the second and eighth transistors T2 and T8 may be connected to the same data line as in the embodiment of the pixel 400 illustrated in FIG. 13.

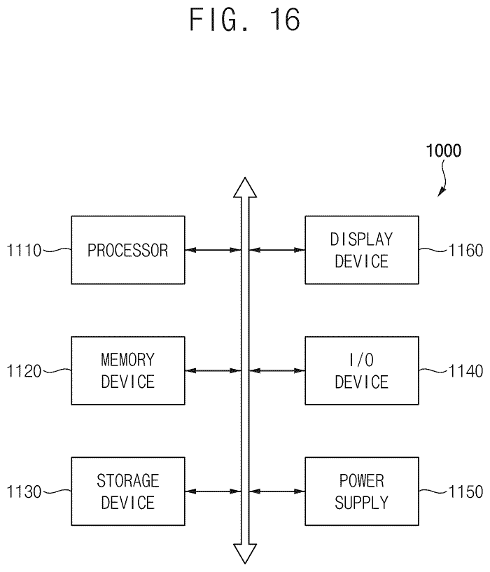

FIG. 16 is a block diagram illustrating an electronic device including a display device according to embodiments.

Referring to FIG. 16, an electronic device 1100 may include a processor 1110, a memory device 1120, a storage device 1130, an input/output (I/O) device 1140, a power supply 1150, and a display device 1160. The electronic device 1100 may further include a plurality of ports for communicating with a video card, a sound card, a memory card, a universal serial bus (USB) device, other electric devices, or the like.

The processor 1110 may perform various computing functions or tasks. The processor 1110 may be an application processor (AP), a microprocessor, a central processing unit (CPU), or the like. The processor 1110 may be coupled to other components via an address bus, a control bus, a data bus, or the like. In some embodiments, the processor 1110 may be further coupled to an extended bus such as, for example, a peripheral component interconnection (PCI) bus.

The memory device 1120 may store data for operations of the electronic device 1100. For example, the memory device 1120 may include at least one non-volatile memory device such as, for example, an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like, and/or at least one volatile memory device such as, for example, a dynamic random access memory (DRAM) device, a static random access memory (SRAM) device, a mobile dynamic random access memory (mobile DRAM) device, or the like.

The storage device 1130 may be a solid state drive (SSD) device, a hard disk drive (HDD) device, a CD-ROM device, or the like. The I/O device 1140 may be an input device such as, for example, a keyboard, a keypad, a mouse, a touch screen, or the like, and an output device such as, for example, a printer, a speaker, or the like. The power supply 1150 may supply power for operations of the electronic device 1100. The display device 1160 may be coupled to other components through the buses or other communication links.

In the display device 1160, each pixel may include a light emitting element, a PWM circuit, a CCG circuit and a connection switch. Light emitting elements of a plurality of pixels may substantially simultaneously start emitting light at a start time point of an emission period. In each of the plurality of pixels, the PWM circuit may transfer a reference voltage to the CCG circuit through the connection switch at a time point corresponding to a voltage level of a PWM data voltage, and the CCG circuit may cause the light emitting element to stop emitting light in response to the reference voltage. The reference voltage applied to the PWM circuit may be higher than or equal to a power supply voltage applied to the CCG circuit. Accordingly, for example, the display device 1160 according to embodiments may drive the light emitting element in a PWM method, and the number of transistors and the number of capacitors of the pixel of the display device 1160 according to embodiments may be reduced compared with the number of transistors and the number of capacitors of a conventional pixel.

Aspects of the embodiments described herein may be applied to any display device 1160 and any electronic device 1100 including the display device 1160. For example, aspects of the embodiments described herein may be applied to a smart phone, a wearable electronic device, a tablet computer, a mobile phone, a television (TV) (e.g., a digital TV, a 3D TV, or the like), a personal computer (PC), a home appliance, a laptop computer, a personal digital assistant (PDA), a portable multimedia player (PMP), a digital camera, a music player, a portable game console, a navigation device, or the like.

The foregoing is illustrative of example embodiments and is not to be construed as limiting thereof. Although example embodiments have been described, those skilled in the art will readily appreciate that many modifications are possible in the embodiments without materially departing from the novel teachings and advantages of the embodiments of the present disclosure. Accordingly, for example, all such modifications are intended to be included within the scope of the embodiments of the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising a plurality of pixels, each of the plurality of pixels comprising:
a light emitting element;
a pulse width modulation (PWM) circuit configured to control an emission time of the light emitting element based on a PWM data voltage, a sweep voltage, and a reference voltage;
a constant current generation (CCG) circuit configured to provide a constant driving current to the light emitting element based on a constant current data voltage and a power supply voltage; and
a connection switch configured to connect the PWM circuit to the CCG circuit,
wherein the light emitting elements of the plurality of pixels substantially simultaneously start emitting light at a start time point of an emission period,
wherein, in each of the plurality of pixels, the PWM circuit transfers the reference voltage to the CCG circuit through the connection switch at a time point corresponding to a voltage level of the PWM data voltage, and the CCG circuit causes the light emitting element to stop emitting light in response to the reference voltage, and
wherein the reference voltage is applied to the PWM circuit, the power supply voltage is applied to the CCG circuit, and the reference voltage is higher than or equal to the power supply voltage.

2. The display device of claim 1, wherein a voltage level of the PWM data voltage for each of the plurality of pixels is determined according to image data for each of the plurality of pixels, and
wherein the constant current data voltage is provided to the plurality of pixels and is the same among the plurality of pixels.

3. The display device of claim 1, wherein the sweep voltage is provided to the plurality of pixels and is the same among the plurality of pixels, and
wherein the sweep voltage gradually decreases in the emission period.

4. The display device of claim 1, wherein the PWM circuit comprises:
a first transistor including a gate, a first terminal, and a second terminal;
a second transistor including a gate configured to receive a first writing signal, a first terminal connected to a first data line, and a second terminal connected to the first terminal of the first transistor;
a third transistor including a gate configured to receive a first emission signal, a first terminal connected to a line associated with transferring the reference voltage, and a second terminal connected to the first terminal of the first transistor;
a fourth transistor including a gate configured to receive a third writing signal, a first terminal connected to the second terminal of the first transistor, and a second terminal connected to the gate of the first transistor; and
a first capacitor including a first electrode connected to a line associated with transferring the sweep voltage and a second electrode connected to the gate of the first transistor.

5. The display device of claim 4, wherein the CCG circuit comprises:
a sixth transistor including a gate configured to receive a second initialization signal, a first terminal connected to a line associated with transferring an anode initialization voltage, and a second terminal connected to an anode of the light emitting element;
a seventh transistor including a gate, a first terminal, and a second terminal;
an eighth transistor including a gate configured to receive a second writing signal, a first terminal connected to a second data line, and a second terminal connected to the first terminal of the seventh transistor;
a ninth transistor including a gate configured to receive the first emission signal, a first terminal connected to a line associated with transferring the power supply voltage, and a second terminal connected to the first terminal of the seventh transistor;
a tenth transistor including a gate configured to receive a fourth writing signal, a first terminal connected to the second terminal of the seventh transistor, and a second terminal connected to the gate of the seventh transistor;
a second capacitor including a first electrode connected to the line associated with transferring the power supply voltage and a second electrode connected to the gate of the seventh transistor; and
an eleventh transistor including a gate configured to receive the first emission signal, a first terminal connected to the second terminal of the seventh transistor, and a second terminal connected to the anode of the light emitting element.

6. The display device of claim 5, wherein the PWM circuit further comprises:
a fifth transistor including a gate configured to receive a first initialization signal, a first terminal connected to a line associated with transferring an initialization voltage, and a second terminal connected to the gate of the first transistor.

7. The display device of claim 6, wherein the connection switch comprises:
a twelfth transistor including a gate configured to receive a second emission signal, a first terminal connected to the second terminal of the first transistor, and a second terminal connected to the gate of the seventh transistor.

8. The display device of claim 7, wherein a frame period for the display device comprises:
an initialization period in which the gates of the first transistors of the plurality of pixels and the gates of the seventh transistors of the plurality of pixels are substantially simultaneously initialized;
a PWM data writing period in which the PWM data voltages are sequentially written to the plurality of pixels on a row basis;
a CCG data writing period in which the constant current data voltage is substantially simultaneously written to the plurality of pixels; and
the emission period in which the light emitting elements of the plurality of pixels substantially simultaneously start emitting light.

9. The display device of claim 8, wherein, in the initialization period,
the first initialization signal, the third writing signal, and the second emission signal have an on-level,
the initialization voltage is applied to the gate of the first transistor through the fifth transistor, and
the initialization voltage is applied to the gate of the seventh transistor through the fifth transistor, the fourth transistor, and the twelfth transistor.

10. The display device of claim 8, wherein, in the PWM data writing period,
the first writing signal and the third writing signal have an on-level,
the fourth transistor diode-connects the first transistor, and
the PWM data voltage is applied to the second electrode of the first capacitor through the second transistor and the diode-connected first transistor.

11. The display device of claim 8, wherein, in the CCG data writing period,
the second writing signal and the fourth writing signal have an on-level,
the tenth transistor diode-connects the seventh transistor, and
the constant current data voltage is applied to the second electrode of the second capacitor through the eighth transistor and the diode-connected seventh transistor.

12. The display device of claim 8, wherein, in the emission period,
the first emission signal and the second emission signal have an on-level,
the sweep voltage gradually decreases, the first transistor is turned on in response to the sweep voltage, and the reference voltage is applied to the seventh transistor through the third transistor, the first transistor and the twelfth transistor, and
the seventh transistor starts providing the constant driving current to the light emitting element at the start time point of the emission period and stops providing the constant driving current in response to the reference voltage.

13. The display device of claim 8, wherein the second initialization signal has an on-level in the initialization period, the PWM data writing period, and the CCG data writing period, and
wherein the sixth transistor applies the anode initialization voltage to the anode of the light emitting element in the initialization period, the PWM data writing period, and the CCG data writing period.

14. The display device of claim 8, wherein the second initialization signal has an on-level in the initialization period, and
wherein the sixth transistor applies the anode initialization voltage to the anode of the light emitting element in the initialization period.

15. The display device of claim 7, wherein the first transistor, second transistor, third transistor, sixth transistor, seventh transistor, eighth transistor, ninth transistor, eleventh transistor, and twelfth transistor are P-type metal oxide semiconductor (PMOS) transistors, and
wherein the fourth transistor, fifth transistor, and tenth transistor are N-type metal oxide semiconductor (NMOS) transistors.

16. The display device of claim 7, wherein the first transistor, second transistor, third transistor, sixth transistor, seventh transistor, eighth transistor, ninth transistor, and eleventh transistor are PMOS transistors, and
wherein the fourth transistor, fifth transistor, tenth transistor, and twelfth transistor are NMOS transistors.

17. The display device of claim 5, wherein the first data line and the second data line are different from each other.

18. The display device of claim 5, wherein the first data line and the second data line are a same data line.

19. The display device of claim 5, wherein the CCG circuit comprises:
a fifth transistor including a gate configured to receive a first initialization signal, a first terminal connected to a line associated with transferring an initialization voltage, and a second terminal connected to the gate of the seventh transistor.

20. A display device comprising a plurality of pixels, each of the plurality of pixels comprising:
a light emitting element;
a first transistor including a gate, a first terminal, and a second terminal;
a second transistor including a gate configured to receive a first writing signal, a first terminal connected to a first data line, and a second terminal connected to the first terminal of the first transistor;
a third transistor including a gate configured to receive a first emission signal, a first terminal connected to a line associated with transferring a reference voltage, and a second terminal connected to the first terminal of the first transistor;
a fourth transistor including a gate configured to receive a third writing signal, a first terminal connected to the second terminal of the first transistor, and a second terminal connected to the gate of the first transistor;
a first capacitor including a first electrode connected to a line associated with transferring a sweep voltage and a second electrode connected to the gate of the first transistor;
a fifth transistor including a gate configured to receive a first initialization signal, a first terminal connected to a line associated with transferring an initialization voltage, and a second terminal connected to the gate of the first transistor;
a sixth transistor including a gate configured to receive a second initialization signal, a first terminal connected to a line associated with transferring an anode initialization voltage, and a second terminal connected to an anode of the light emitting element;
a seventh transistor including a gate, a first terminal, and a second terminal;
an eighth transistor including a gate configured to receive a second writing signal, a first terminal connected to a second data line, and a second terminal connected to the first terminal of the seventh transistor;
a ninth transistor including a gate configured to receive the first emission signal, a first terminal connected to a line associated with transferring a power supply voltage, and a second terminal connected to the first terminal of the seventh transistor;
a tenth transistor including a gate configured to receive a fourth writing signal, a first terminal connected to the second terminal of the seventh transistor, and a second terminal connected to the gate of the seventh transistor;
a second capacitor including a first electrode connected to the line associated with transferring the power supply voltage and a second electrode connected to the gate of the seventh transistor;
an eleventh transistor including a gate configured to receive the first emission signal, a first terminal connected to the second terminal of the seventh transistor, and a second terminal connected to the anode of the light emitting element; and
a twelfth transistor including a gate configured to receive a second emission signal, a first terminal connected to the second terminal of the first transistor, and a second terminal connected to the gate of the seventh transistor.
